(19) United States
(12) Patent Application Publication
(10) Pub. No.: US 2017/0200693 A1
(43) Pub. Date: Jul. 13, 2017

(54) ELECTRONIC COMPONENT

(71) Applicant: HAMAMATSU PHOTONICS K.K., Hamamatsu-shi, Shizuoka (JP)

(72) Inventors: Yoshimaro FUJII, Hamamatsu-shi (JP); Hiroshi OGURI, Hamamatsu-shi (JP); Akira SAKAMOTO, Hamamatsu-shi (JP); Tomoya TAGUCHI, Hamamatsu-shi (JP)

(73) Assignee: HAMAMATSU PHOTONICS K.K., Hamamatsu-shi, Shizuoka (JP)

(21) Appl. No.: 15/320,835

(22) PCT Filed: Aug. 5, 2015
(86) PCT No.: PCT/JP2015/072215

§ 371 Date: Dec. 21, 2016

(30) Foreign Application Priority Data
Aug. 7, 2014 (JP) 2014-161240

(51) Int. Cl. H01L 23/00; H01L 31/0216; H01L 31/02; H01L 31/0203

(52) U.S. Cl. CPC H01L 24/73; H01L 31/0203; H01L 31/02161; H01L 31/02002; H01L 24/29; H01L 24/13; H01L 2224/13144; H01L 2224/13111; H01L 2224/28105; H01L 2224/29083; H01L 2224/29166; H01L 2224/29171; H01L 2224/29169; H01L 2224/29144; H01L 2224/29011; H01L 2224/29013; H01L 2224/29018; H01L 2924/014; H01L 2924/12043; H01L 2924/12042; H01L 2224/73103

(57) ABSTRACT

An electronic component includes a base, a laminate of a plurality of conductive metal material layers, and a solder layer made of Au—Sn alloy solder. The laminate is disposed on the base. The solder layer is disposed on the laminate. The laminate includes a surface layer made of Au as the conductive metal material layer constituting an outermost layer. The surface layer includes a solder layer-disposing region in which the solder layer is disposed and a solder layer-empty region in which the solder layer is not disposed. The solder layer-disposing region and the solder layer-empty region are spatially separated from each other.

### TECHNICAL FIELD

The present invention relates to an electronic component.

### BACKGROUND ART

Known electronic components include a photodiode, a terminal disposed on a portion other than a light-receiving unit on an upper surface of the photodiode, and a bump disposed on the terminal (see, for example, Patent Literature 1). On this electronic component, an IC chip is mounted as another electronic component.

### CITATION LIST

### Patent Literature

Patent Literature 1: Japanese Unexamined Patent Publication No. 2000-307133

### SUMMARY OF INVENTION

### Technical Problem

An object of an aspect of the present invention is to provide an electronic component capable of appropriately mounting another electronic component even when mounting the other electronic component using Au—Sn alloy solder.

### Solution to Problem

An electronic component according to one aspect of the present invention includes a base, a laminate of a plurality of conductive metal material layers, and a solder layer. The laminate is disposed on the base. The solder layer is disposed on the laminate, and is made of Au—Sn alloy solder. The laminate includes a surface layer made of Au as a conductive metal material layer constituting an outermost layer. The surface layer includes a solder layer-disposing region in which the solder layer is disposed and a solder layer-empty region in which the solder layer is not disposed. The solder layer-disposing region and the solder layer-empty region are spatially separated from each other.

In the electronic component according to the aspect, the surface layer made of Au, which constitutes the outermost layer of the laminate, includes the solder layer-disposing region and the solder layer-empty region, and the solder layer-disposing region and the solder layer-empty region are spatially separated from each other. When mounting another electronic component on the electronic component according to the one aspect, the solder layer (Au—Sn alloy solder) disposed on the laminate melts. Flow of the molten Au—Sn alloy solder from the solder layer-disposing region to the solder layer-empty region is suppressed.

There may be a case where heat history of the solder layer and of the surface layer cause Au in the surface layer to diffuse into the solder layer and as a result, the composition of the Au—Sn alloy solder changes. When the composition of the Au—Sn alloy solder has changed, there is a risk that a melting point of the Au—Sn alloy solder varies, or another electronic component is bonded nonuniformly. Since the solder layer-disposing region and the solder layer-empty region are spatially separated from each other as described above, even if Au in the surface layer diffuses into the solder layer, Au in the solder layer-empty region does not diffuse into the solder layer. Since an amount of Au diffused from the surface layer is suppressed, the change in the composition of the Au—Sn alloy solder is suppressed.

In view of the above, according to the aspect, it is possible to appropriately mount another electronic component even when mounting the other electronic component using the Au—Sn alloy solder.

The solder layer-disposing region may be located inside the solder layer-empty region to be surrounded by the solder layer-empty region, and the whole circumference of the solder layer-disposing region may be spatially separated from the solder layer-empty region. In which case, the flow of the molten Au—Sn alloy solder from the solder layer-disposing region to the solder layer-empty region can be more securely suppressed. Since the amount of Au diffused from the solder layer-disposing region is further suppressed, the change in the composition of the Au—Sn alloy solder can be securely suppressed.

The solder layer-disposing region and the solder layer-empty region may be spatially separated from each other by a slit formed in the surface layer. In which case, a configuration can be easily realized in which the solder layer-disposing region and the solder layer-empty region are spatially separated from each other.

The solder layer may be disposed on the laminate through a barrier layer including Pt. In which case, since the diffusion of Au from the solder layer-disposing region is prevented, the change in the composition of the Au—Sn alloy solder can be more securely suppressed.

### Advantageous Effects of Invention

According to the one aspect of the present invention, it is possible to provide an electronic component capable of appropriately mounting another electronic component even when mounting the other electronic component using the Au—Sn alloy solder.

### BRIEF DESCRIPTION OF DRAWINGS

FIG. 1 is a plan view illustrating an electronic component according to an embodiment.

FIG. 2 is a view for explaining a sectional configuration along a line II-II illustrated in FIG. 1.

FIG. 3 is a view for explaining a sectional configuration of an electronic component according to a variation of the embodiment.

FIG. 4 is a view for explaining a process of forming a solder layer.

FIG. 5 is a view for explaining a sectional configuration of an electronic component in which a solder layer-disposing region and a solder layer-empty region are not spatially separated from each other.

FIG. 6 is a plan view illustrating an electronic component according to another variation of the embodiment.

FIG. 7 is a view for explaining a sectional configuration of the electronic component according to the other variation of the embodiment.

FIG. 8 is a plan view illustrating an electronic component according to another variation of the embodiment.

### DESCRIPTION OF EMBODIMENTS

Hereinafter, an embodiment of the present invention will be described in detail with reference to the drawings. In the description, the same elements or elements with the same functionality will be denoted by the same reference signs, without redundant description.

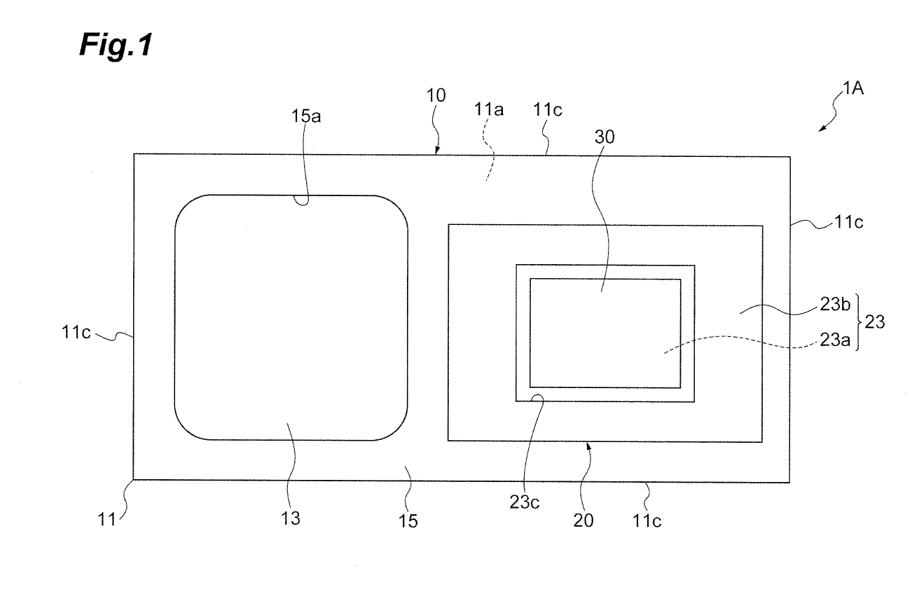

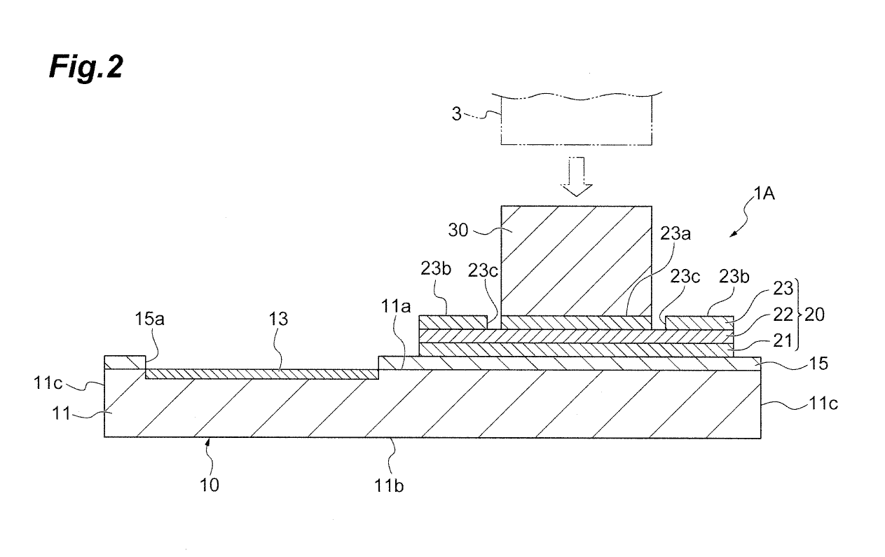

With reference to FIGS. 1 and 2, a configuration of an electronic component 1A according to the embodiment will be described. FIG. 1 is a plan view of the electronic component according to the embodiment. FIG. 2 is a view for explaining a sectional configuration along a line II-II illustrated in FIG. 1.

The electronic component 1A includes a base 10, a laminate 20, and a solder layer 30. The electronic component 1A functions, for example, as a sub-mount substrate on which another electronic component 3 is mounted. The other electronic component 3 is, for example, a laser diode. The term “to mount” herein includes, as the meaning thereof, “to connect only physically” in addition to “to connect electrically and physically.”

The base 10 includes a semiconductor substrate 11. The semiconductor substrate 11 is a silicon substrate of a first conductivity type (for example, N-type) that includes a pair of principal surfaces 11a and 11b opposing each other, and side surfaces 11e. The side surfaces 11c extend in a direction that the pair of principal surfaces 11a and 11b opposing each other to couple the pair of principal surfaces 11a and 11b. In the embodiment, the semiconductor substrate 11 presents a rectangular shape in a plan view, and includes four side surfaces 11c as illustrated in FIG. 1.

The semiconductor substrate 11 includes a first semiconductor region 13 of a second conductivity type (for example, P-type) located on a principal surface 11a side. The first semiconductor region 13 is a region to which a dopant of a second conductivity type (such as boron) is added. A dopant concentration of the first semiconductor region 13 is higher than that of the semiconductor substrate 11. The first semiconductor region 13 is formed by adding the dopant of the second conductivity type to the semiconductor substrate 11 from the principal surface 11a side, for example, by an ion implantation method or a diffusion method.

In the base 10, a P—N junction is formed by the semiconductor substrate 11 and the first semiconductor region 13. That is, the base 10 is a front-illuminated photodiode in which the principal surface 11a is a light incident surface. The first semiconductor region 13 constitutes a photosensitive region together with the semiconductor substrate 11. When a laser diode as the other electronic component 3 is mounted on the electronic component 1A, the photodiode monitors an output of the laser diode.

The base 10 includes a passivation film 15. The passivation film 15 is disposed on the principal surface 11a of the semiconductor substrate 11. In the passivation film 15, an opening 15a is formed at a position corresponding to the first semiconductor region 13. Light is incident onto the first semiconductor region 13 (photosensitive region) through the opening 15a formed in the passivation film 15. The passivation film 15 is made of, for example, SiN. The passivation film 15 is formed, for example, by a chemical vapor deposition (CVD) method. In the embodiment, illustration of a cathode electrode (pad) and an anode electrode (pad) connected to the photodiode is omitted.

The laminate 20 is disposed on the base 10 (passivation film 15). In detail, the laminate 20 is disposed on a region of the passivation film 15 where the opening 15a is not formed. The laminate 20 includes a plurality of conductive metal material layers. In the embodiment, the laminate 20 includes three conductive metal material layers 21, 22, and 23. Each of the conductive metal material layers 21, 22, and 23 is a layer which is made of a conductive metal material. Regarding the three conductive metal material layers 21, 22, and 23, the conductive metal material layer 21, the conductive metal material layer 22, and the conductive metal material layer 23 are stacked on the base 10 in this order. Each of the conductive metal material layers 21, 22, and 23 is formed, for example, by a vacuum deposition method or a sputtering method.

The conductive metal material layer 21 constitutes a layer in contact with the base 10 (passivation film 15). The conductive metal material layer 21 enhances the adhesion to the base 10 (passivation film 15). The conductive metal material layer 21 is made of, for example, Ti. The thickness of the conductive metal material layer 21 is, for example, 0.1 to 0.2 μm. The conductive metal material layer 21 may be made of Cr or the like other than Ti.

The conductive metal material layer 22 constitutes an intermediate barrier layer. The conductive metal material layer 22 prevents a metal material (metal atom) from diffusing from the other conductive metal material layers 21 and 23. The conductive metal material layer 22 is made of, for example, Pt. The thickness of the conductive metal material layer 22 is, for example, 0.2 to 0.3 μm.

The conductive metal material layer 23 constitutes an outermost layer of the laminate 20. That is, the conductive metal material layer 23 constitutes a surface layer. The conductive metal material layer 23 is made of, for example, Au. The thickness of the conductive metal material layer 23 is, for example, 0.1 to 0.5 μm.

The conductive metal material layer 23 includes a solder layer-disposing region 23a in which the solder layer 30 is disposed and a solder layer-empty region 23b in which the solder layer 30 is not disposed. The solder layer-disposing region 23a and the solder layer-empty region 23b are spatially separated from each other on the conductive metal material layer 22. That is, in a region where the solder layer-disposing region 23a and the solder layer-empty region 23b are spatially separated from each other, the conductive metal material layer 22 is exposed.

In the embodiment, the solder layer-disposing region 23a is located inside the solder layer-empty region 23b to be surrounded by the solder layer-empty region 23b, and the whole circumference of the solder layer-disposing region 23a is spatially separated from the solder layer-empty region 23b. The solder layer-disposing region 23a and the solder layer-empty region 23b are spatially separated from each other by a slit 23c formed in the conductive metal material layer 23.

The solder layer 30 is made of Au—Sn alloy solder, and is disposed on the laminate 20 (solder layer-disposing region 23a of the conductive metal material layer 23). The solder layer 30 is in contact with the conductive metal material layer 23 (solder layer-disposing region 23a). The solder layer 30 is formed, for example, by a lift-off method using a photoresist (negative photoresist). The thickness of the solder layer 30 is, for example, 2.0 to 5.0 μm.

As described above, in the embodiment, the conductive metal material layer 23, which is made of Au, includes the solder layer-disposing region 23a and the solder layer-empty region 23b, and the solder layer-disposing region 23a and the solder layer-empty region 23b are spatially separated from each other. When mounting the other electronic component 3 on the electronic component 1A, the solder layer 30 (Au—Sn alloy solder) disposed on the laminate 20 melts. Flow of the molten Au—Sn alloy solder from the solder layer-disposing region 23a to the solder layer-empty region 23b is suppressed.

There may be a case where heat history of the solder layer 30 and of the conductive metal material layer 23 in a manufacturing process of the electronic component 1A cause Au in the conductive metal material layer 23 to diffuse into the solder layer 30 and as a result, the composition of the Au—Sn alloy solder changes. When the composition of the Au—Sn alloy solder has changed, there is a risk that a melting point of the Au—Sn alloy solder varies, or the other electronic component 3 is bonded nonuniformly.

Since the solder layer-disposing region 23a and the solder layer-empty region 23b are spatially separated from each other in the embodiment, even if Au in the conductive metal material layer 23 diffuses into the solder layer 30, Au in the solder layer-empty region 23b does not diffuse into the solder layer 30. Since an amount of Au diffused from the conductive metal material layer 23 is suppressed, the change in the composition of the Au—Sn alloy solder is suppressed.

As a result, according to the electronic component 1A, it is possible to appropriately mount the other electronic component 3 even when mounting the other electronic component 3 using the Au—Sn alloy solder.

In the embodiment, the solder layer-disposing region 23a is located inside the solder layer-empty region 23b to be surrounded by the solder layer-empty region 23b, and the whole circumference of the solder layer-disposing region 23a is spatially separated from the solder layer-empty region 23b. Consequently, the flow of the molten Au—Sn alloy solder from the solder layer-disposing region 23a to the solder layer-empty region 23b can be more securely suppressed. Since the amount of Au diffused from the solder layer-disposing region 23a is further suppressed, the change in the composition of the Au—Sn alloy solder can be securely suppressed.

In the embodiment, the solder layer-disposing region 23a and the solder layer-empty region 23b are spatially separated from each other by a slit formed in the conductive metal material layer 23. Consequently, a configuration can be easily realized in which the solder layer-disposing region 23a and the solder layer-empty region 23b are spatially separated from each other.

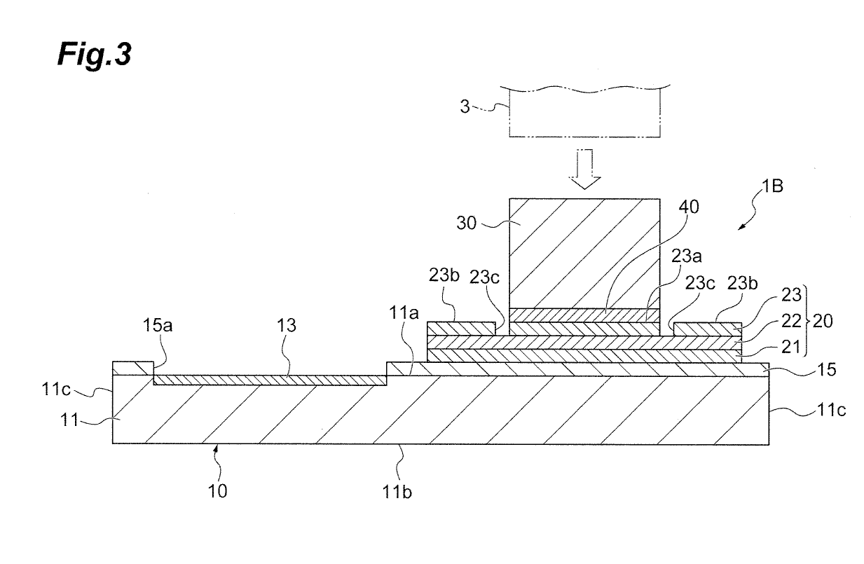

Next, with reference to FIG. 3, a configuration of an electronic component 1B according to a variation of the embodiment will be described. FIG. 3 is a view for explaining a sectional configuration of the electronic component according to the variation of the embodiment.

The electronic component 1B includes a base 10, a laminate 20, a solder layer 30, and a barrier layer 40. As with the case of the electronic component 1A, the electronic component 1B also functions, for example, as a sub-mount substrate on which another electronic component 3 is mounted.

The barrier layer 40 is disposed between the laminate 20 and the solder layer 30. The barrier layer 40 is in contact with the laminate 20 (conductive metal material layer 23) and the solder layer 30. That is, the solder layer 30 is disposed on the laminate 20 through the barrier layer 40. The barrier layer 40 is made of Pt. The barrier layer 40 is formed, for example, by a lift-off method together with the solder layer 30. The thickness of the barrier layer 40 is, for example, 0.2 to 0.3 μm.

In the variation, the barrier layer 40 prevents Au from diffusing from the conductive metal material layer 23 (solder layer-disposing region 23a). Consequently, it is possible to more securely suppress the change in the composition of the Au—Sn alloy solder in the electronic component 1B.

In a case where the barrier layer 40 is disposed between the laminate 20 and the solder layer 30, it is expected that the flow of the molten Au—Sn alloy solder from the solder layer-disposing region 23a to the solder layer-empty region 23b is suppressed even when the solder layer-disposing region 23a and the solder layer-empty region 23b are not spatially separated from each other. However, for the event described below, it is difficult to suppress the above-described flow of the molten Au—Sn alloy solder even when there is the barrier layer 40.

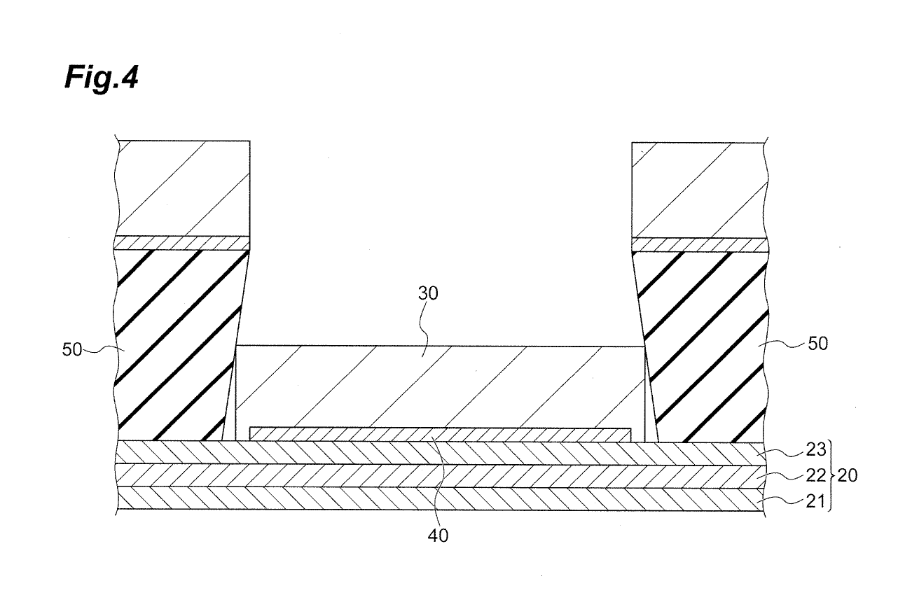

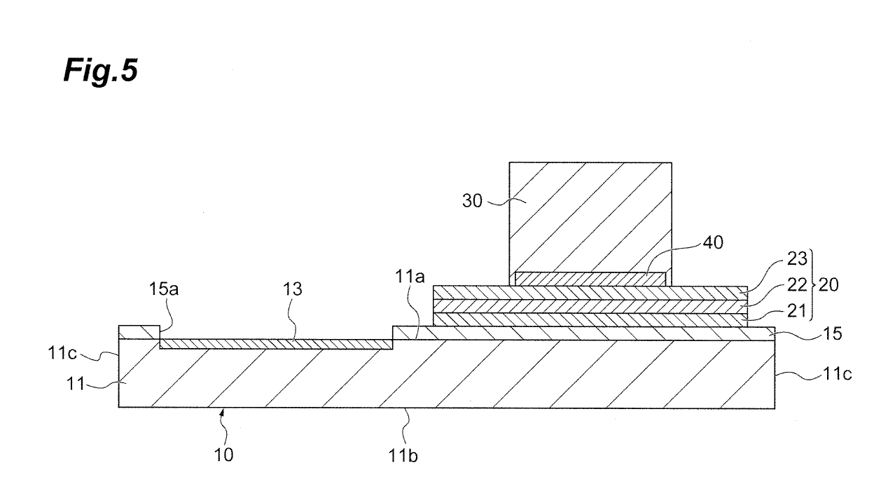

When the solder layer 30 is formed by the lift-off method described above, the solder layer 30 is formed larger than the barrier layer 40, as illustrated in FIGS. 4 and 5, due to the shape of a photoresist 50. That is, the solder layer 30 is formed to cover the barrier layer 40 and to be in contact with the laminate 20 (conductive metal material layer 23). The thickness of the solder layer 30 is generally larger than the thickness of the barrier layer 40. Consequently, the solder layer 30 is likely to spread in a direction in parallel to the solder layer 30, which makes the solder layer 30 to be formed much larger than the barrier layer 40. When the solder layer 30 is in contact with the conductive metal material layer 23, there is a risk that the molten Au—Sn alloy solder wet-spreads on the conductive metal material layer 23. Consequently, the molten Au—Sn alloy solder flows to the solder layer-empty region 23b from the solder layer-disposing region 23a.

In the variation, as with the case of the electronic component 1A, the solder layer-disposing region 23a and the solder layer-empty region 23b are spatially separated from each other. Consequently, the flow of the molten Au—Sn alloy solder from the solder layer-disposing region 23a to the solder layer-empty region 23b is securely suppressed.

The embodiment of the present invention has been described above. However, the present invention is not necessarily limited to the embodiment described above, and various modifications are possible without departing from the gist thereof.

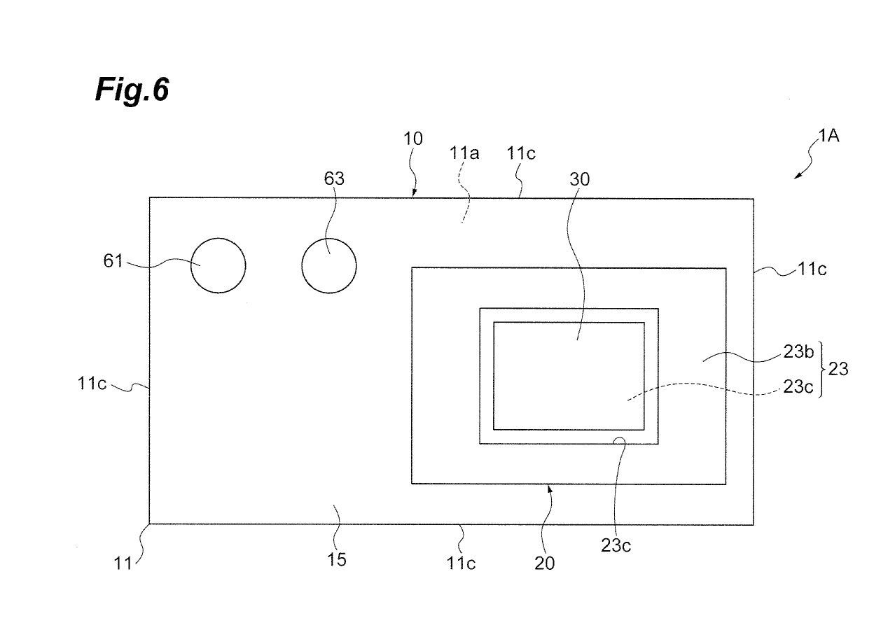

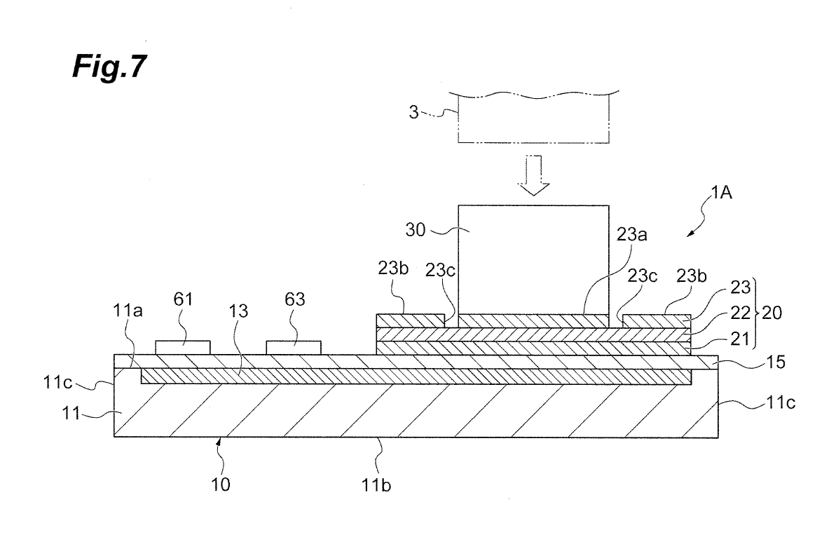

A base 10 is not limited to the front-illuminated photodiode. The base 10 may be an edge-illuminated photodiode in which at least one side surface 11c is a light incident surface as illustrated in FIGS. 6 and 7. In an electronic component 1A illustrated in FIGS. 6 and 7, a cathode electrode (pad) 61 and an anode electrode (pad) 63 are disposed to be exposed from a passivation film 15. FIG. 6 is a plan view illustrating an electronic component according to another variation of the embodiment. FIG. 7 is a view for explaining a sectional configuration of the electronic component according to the other variation of the embodiment.

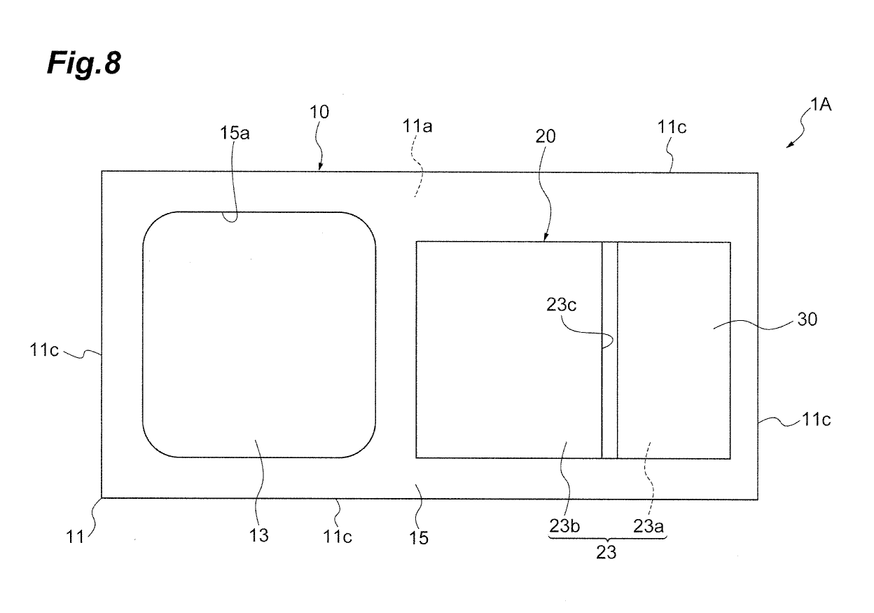

A solder layer-disposing region 23a is not necessarily located inside a solder layer-empty region 23b to be surrounded by the solder layer-empty region 23b, and the whole circumference of the solder layer-disposing region 23a is not necessarily spatially separated from the solder layer-empty region 23b. For example, the solder layer-disposing region 23a and the solder layer-empty region 23b may be divided by a linear slit 23c to be spatially separated from each other as illustrated in FIG. 8.

A laminate 20 is not necessary to include three conductive metal material layers 21, 22, and 23. The laminate 20 may include two conductive metal material layers, or may include four or more conductive metal material layers. Also in those cases, it is sufficient that the conductive metal material layer which constitutes an outermost layer of the laminate 20, in other words, a surface layer, includes Au.

A base 10 is not necessarily a photodiode, and there is no need for the base 10 to include a semiconductor substrate 11. The base 10 may include, for example, a ceramic substrate or a glass substrate, instead of the semiconductor substrate 11. As the ceramic substrate, an aluminum nitride (AlN) substrate, an alumina (Al2O3) substrate, or the like is used.

There is no need for another electronic component 3 mounted on an electronic component 1A or 1B to be a laser diode. The other electronic component 3 may be, for example, a light-receiving element, a light-emitting element, a semiconductor package, a circuit substrate, an active component, or a passive component.

### INDUSTRIAL APPLICABILITY

The present invention can be applicable to an electronic component such as a sub-mount substrate.

### REFERENCE SIGNS LIST

1A, 1B: Electronic component, 10: Base, 20: Laminate, 21, 22, 23: Conductive metal material layer, 23a: solder layer-disposing region, 23b: Solder layer-empty region, 23c: Slit, 30: Solder layer, 40: Barrier layer.

1. An electronic component comprising:
a base;
a laminate of a plurality of conductive metal material layers, the laminate being disposed on the base; and
a solder layer made of Au—Sn alloy solder, the solder layer being disposed on the laminate, wherein
the laminate includes a surface layer made of Au as the conductive metal material layer constituting an outermost layer,
the surface layer includes a solder layer-disposing region in which the solder layer is disposed and a solder layer-empty region in which the solder layer is not disposed, and
the solder layer-disposing region and the solder layer-empty region are spatially separated from each other.

2. The electronic component according to claim 1, wherein
the solder layer-disposing region is located inside the solder layer-empty region to be surrounded by the solder layer-empty region, and the whole circumference of the solder layer-disposing region is spatially separated from the solder layer-empty region.

3. The electronic component according to claim 1, wherein
the solder layer-disposing region and the solder layer-empty region are spatially separated from each other by a slit formed in the surface layer.

4. The electronic component according to claim 1, wherein
the solder layer is disposed on the laminate through a barrier layer comprising Pt.
